(19) United States
(12) Patent Application Publication
(10) Pub. No.: US 2015/0104944 A1
(43) Pub. Date: Apr. 16, 2015

(54) METHOD OF FORMING PATTERNS FOR SEMICONDUCTOR DEVICE

(71) Applicant: SAMSUNG ELECTRONICS CO., LTD., Suwon-si (KR)

(72) Inventors: Ki Won PARK, Suwon-si (KR); Ju Hyun KIM, Yongin-si (KR); Yu Seung KIM, Seoul (KR); Sang Yeob SONG, Suwon-si (KR); Tae Hyun LEE, Seoul (KR)

(73) Assignee: SAMSUNG ELECTRONICS CO., LTD., Suwon-si (KR)

(21) Appl. No.: 14/276,502

(22) Filed: May 13, 2014

(30) Foreign Application Priority Data
Oct. 15, 2013 (KR) 10-2013-0122522

(51) Int. Cl. H01L 21/308

(52) U.S. Cl. CPC H01L 21/308
USPC 438/703

(57) ABSTRACT

There is provided a method of forming patterns for a semiconductor device. The method sequentially forming a first mask layer and a second mask layer on a substrate. The method also includes forming a second mask pattern layer by patterning the second mask layer. The method further includes forming a first mask pattern layer having a negative slope portion, by etching the first mask layer exposed through the second mask pattern layer. The method also includes forming a thin film layer on the substrate exposed through the first mask pattern layer.

### CROSS-REFERENCE TO RELATED APPLICATION

This application claims priority to and benefit of Korean Patent Application No. 10-2013-0122522 filed on Oct. 15, 2013, with the Korean Intellectual Property Office, the entire content of which are incorporated herein by reference.

### TECHNICAL FIELD

The present disclosure relates to a method of forming patterns for a semiconductor device.

### BACKGROUND

Diverse types of thin film may be used in manufacturing semiconductor devices. Such thin films may have differing characteristics according to the materials of which they are formed, the manufacturing process conditions thereof, as well as properties of a base film and the like, one of which is stress. Such stress is generated by expansion and contraction according to crystalline properties, a difference of a thermal expansion coefficient of the film to that of a base film, a processing atmosphere, and the like. In a case in which a thin film has tensile or compressive stress, the shape of the thin film may be deformed, and a lower layer may be deformed thereby.

Therefore, development of an advanced processing technology is needed for forming thin film patterns with precision.

### SUMMARY

An aspect of the present disclosure provides a method of forming patterns for a semiconductor device, for improving a reliability of semiconductor devices by using a high-hardness mask pattern having a negative slope.

According to an aspect of the present disclosure, a method of forming patterns for a semiconductor device includes sequentially forming a first mask layer and a second mask layer on a substrate. The method also includes forming a second mask pattern layer by patterning the second mask layer. The method further includes forming a first mask pattern layer having negative slope portions, the width of which decreases from an area adjacent to the second mask pattern layer to the substrate, by etching the first mask layer exposed through the second mask pattern layer. The method also includes forming a thin film layer on the substrate exposed through the first mask pattern layer.

The thin film layer may be formed on an upper surface of the substrate to be spaced apart from the first mask pattern layer.

The forming of the thin film layer may include depositing a material for forming the thin film layer on the substrate on which the first mask pattern layer and the second mask pattern layer are sequentially formed. The forming may also include removing the second mask pattern layer.

The method of forming patterns for a semiconductor device may further include removing the second mask pattern layer before the forming of the thin film layer.

The method of forming patterns for a semiconductor device may further include removing the first mask pattern layer after the forming of the thin film layer.

The forming the thin film layer may be performed at a temperature higher than a temperature of a softening point of the second mask pattern layer.

The forming the first mask pattern layer may include wet etching at least a portion of the first mask layer.

The first mask layer may include a material, a hardness of which is higher than a hardness of the second mask layer.

The density of the first mask layer may change in a vertical direction to the upper surface of the substrate.

A porosity of the first mask layer may change in a vertical direction to the upper surface of the substrate.

The porosity of the first mask layer may be greater in the vicinity of the substrate than that in the vicinity of the second mask layer

The porosity of the first mask layer may gradually increase toward an area facing the substrate from an area facing the second mask layer.

The thin film layer may have tensile stress or compressive stress applied thereto.

The first mask layer may include a dielectric material or an insulating material.

According to another aspect of the present disclosure, a method of forming patterns for a semiconductor device includes forming a mask pattern layer having a negative slope area on a substrate, wherein the mask pattern layer includes a non-photosensitive material. The method further includes forming a thin film layer on a substrate exposed through the mask pattern layer.

By way of using a high-hardness mask pattern having a negative slope, a method of forming patterns for a semiconductor device improving a reliability of semiconductor devices is provided.

### BRIEF DESCRIPTION OF DRAWINGS

The above and other aspects, features and other advantages of the present disclosure will be more clearly understood from the following detailed description taken in conjunction with the accompanying drawings, in which like reference characters may refer to the same or similar parts throughout the different views. The drawings are not necessarily to scale, emphasis instead being placed upon illustrating the principles of the embodiments of the inventive concept. In the drawings, the thickness of layers and regions may be exaggerated for clarity.

FIG. 1 is a schematic plan view illustrating an exemplary semiconductor device pattern implemented by applying the method of forming patterns for a semiconductor device, according to an exemplary embodiment of the present disclosure.

FIGS. 2 through 6 are schematic cross-sectional views illustrating, in sequence, the method of forming patterns for a semiconductor device, according to an exemplary embodiment of the present disclosure.

FIG. 7 is a schematic plan view illustrating an exemplary semiconductor device pattern implemented by applying the method of forming patterns for a semiconductor device, according to an exemplary embodiment of the present disclosure.

FIGS. 8 through 10 are schematic cross-sectional views illustrating, in sequence, the method of forming patterns for a semiconductor device, according to an exemplary embodiment of the present disclosure.

FIG. 11 is a schematic cross-sectional view illustrating a process of the method forming patterns for a semiconductor device, according to an exemplary embodiment of the present disclosure.

FIG. 12 is a schematic cross-sectional view illustrating a semiconductor device, according to an exemplary embodiment of the present disclosure.

FIGS. 13 through 15 are schematic cross-sectional views illustrating the method of manufacturing a semiconductor device, according to an exemplary embodiment of the present disclosure.

FIG. 16 is a schematic cross-sectional view illustrating a semiconductor device, according to an exemplary embodiment of the present disclosure.

### DETAILED DESCRIPTION

Exemplary embodiments of the present disclosure are described in detail with reference to the accompanying drawings.

The disclosure may, however, be exemplified in many different forms and should not be construed as being limited to the specific exemplary embodiments set forth herein. Rather, these exemplary embodiments of the present disclosure are provided so that this disclosure will be thorough and complete, and will fully convey the scope of the disclosure to those skilled in the art.

In the drawings, the shapes and dimensions of elements may be exaggerated for clarity, and the same reference numerals will be used throughout to designate the same or like elements.

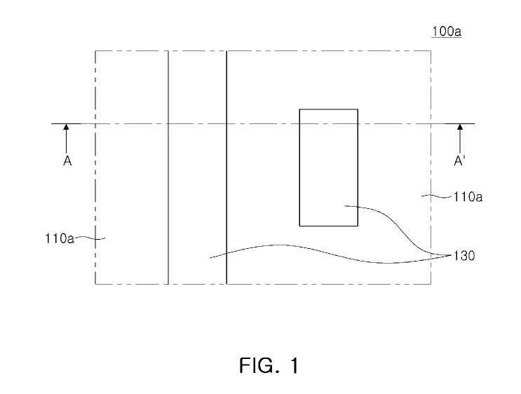

FIG. 1 is a schematic plan view illustrating an exemplary semiconductor device pattern implemented by applying the method of forming patterns for a semiconductor device, according to an exemplary embodiment of the present disclosure.

With reference to FIG. 1, a semiconductor device 100a may include a thin film layer 130 having a linear form and a rectangular form extending in a single direction, and a first mask pattern layer 110a may be disposed in the vicinity of the thin film layer 130.

The thin film layer 130 may be a layer having tensile stress or compressive stress applied thereto and may be formed of, for example, a metallic or a dielectric material. According to a present exemplary embodiment, the shape of the thin film layer 130 is exemplary, and the thin film layer 130 may be manufactured in diverse manners to have different shapes.

The first mask layer 110a may be formed of a dielectric material or an insulating material, and may be formed of, for example, Plasma Enhanced Oxide (PEOX). Moreover, the first mask layer 110a may be formed of a non-photosensitive material. A density and a porosity of the first mask layer 110a may change in a vertical direction upwardly from a substrate 101 (shown in FIG. 2). For example, the first mask pattern layer 110a may include multiple layers having varying densities, and the density of a lower layer may be lower than that of an upper layer. The first mask pattern layer 110a may include multiple layers having varying levels of porosity, and the porosity of a lower layer may be greater than that of an upper layer. Moreover, the density or the porosity of the first mask layer 110a may gradually change from an upper portion to a lower portion thereof.

According to a present exemplary embodiment of the present disclosure, as described in detail as below with reference to FIGS. 2 through 6, the first mask layer 110a may be a structural element of the semiconductor device 100a by remaining at a final structure while performing the role of a mask layer forming the thin film layer 130.

FIGS. 2 through 6 are schematic cross-sectional views illustrating, in sequence, the method of forming patterns for a semiconductor device according to an exemplary embodiment of the present disclosure. FIGS. 2 through 6 depict cross-sectional views cut along line A-A′ in the plan view of FIG. 1.

With reference to FIG. 2, the first mask layer 110 and the second mask layer 120 are sequentially formed on the substrate 101. The first mask layer 110 and the second mask layer 120 are mask layers for forming the thin film layer 130 of FIG. 1.

The substrate 101 may be an ordinary semiconductor substrate such as a silicon (Si) substrate. Moreover, the substrate 101 may include the semiconductor substrate and a portion of semiconductor devices formed on the semiconductor substrate.

The first mask layer 110 may be formed of, for example, an insulating material, and formed of a silicon oxide (SiO₂) such as PEOX. The first mask layer 110 may include a material, the hardness of which is higher than the hardness of the second mask layer 120, and which may have a superior stability at high temperature. The first mask layer 110 may be formed by using a method of Chemical Vapor Deposition (CVD).

The first mask layer 110 may be formed to have a thickness 1.5 to 3 times greater than that of the thin film layer 130, considering a thickness of the thin film layer 130 to be formed. At a time at which the first mask layer 110 is formed, the first mask layer 110 may be formed to have variable density and porosity in a vertical direction upwards from the substrate 101 by controlling RF power, an amount of source gas, or the like. Thereby, the porosity of the first mask layer 110 may be greater in the vicinity of the substrate 101 than that in the vicinity of the second mask layer 120. For example, the mask layer 110 may include multiple layers having differing densities or porosities.

The second mask layer 120 may be formed of a material different to that of the first mask layer 110, and may be formed of, for example, a photo-resist layer. The second mask layer 120 may be formed on the first mask layer 110 through spin coating. The second mask layer 120 may have a first thickness (T1), where T1 may be equal to or less than the second thickness (T2) of the first mask layer 110, but the present embodiment is not limited to the specific embodiments set forth in the drawings.

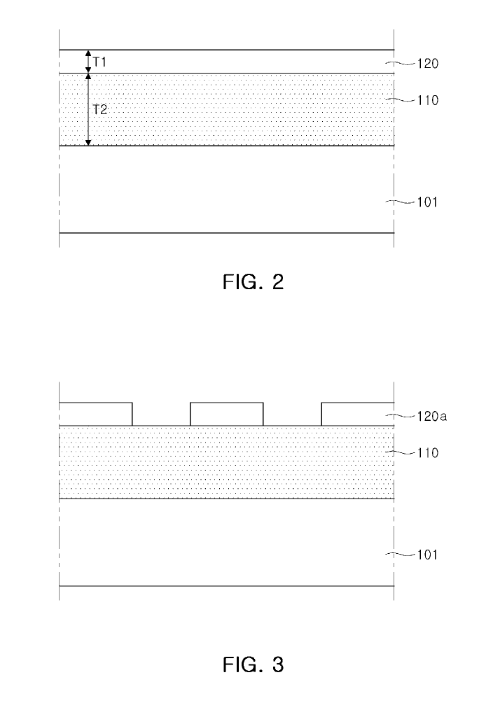

With reference to FIG. 3, the second mask pattern layer 120a may be formed by patterning the second mask layer 120.

The second mask pattern layer 120a may be formed by removing the second mask layer 120 in an area in which the thin film layer 130 of FIG. 1 can be formed by performing processes of exposing and developing the second mask layer 120.

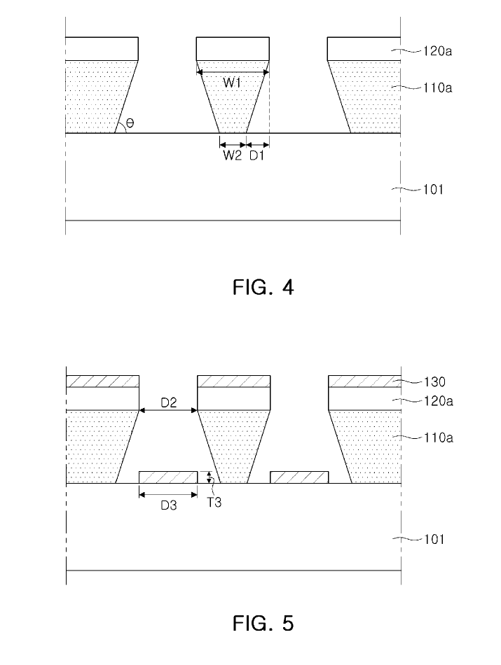

With reference to FIG. 4, by etching the first mask layer 110 exposed through the second mask pattern layer 120a, the first mask pattern layer 110a may be formed.

The first mask layer 110 may be etched by, for example, wet etching. The first mask pattern layer 110a may be formed to have a negative slope portion, the width of which decreases from an area adjacent to the second mask pattern layer 120a to the substrate 101. Through the negative slope portion, the first mask pattern layer 110a may have a predetermined angle of less than 90° with respect to an upper surface of the substrate 101. Such a negative slope may be formed by forming portions of the first mask layer 110 to have differing densities or porosities and etching different portions thereof at different rates. The present inventive concept is not limited thereto, according to exemplary embodiments, even in a case in which the characteristics of the first mask layer 110 as a whole are substantially uniform; the negative slope may be formed by performing plural etching operations under differing conditions.

The first mask pattern 110a may have a first width W1 in an area facing the second mask pattern layer 120a, and a second width W2 narrower than the first width W1 in an area facing the substrate 101. In particular, an edge of the first mask pattern layer 110a facing the substrate 101 can be positioned inwardly from an edge of the second mask pattern layer 120a by a predetermined distance D1.

With reference to FIG. 5, the thin film layer 130 may be formed on the substrate 101 on which the first mask pattern layer 110a and the second mask pattern layer 120a are sequentially formed.

The thin film layer 130 may be formed by depositing material from directly above an upper surface or aside surface of the substrate 101. In addition, the deposited material may be provided from above the substrate 101 at a predetermined angle to be deposited thereon, that is, the material to be deposited may be provided in a vertical direction, or a sloped angle, with respect to the substrate 101.

Therefore, the width D3 of the thin film 130 on the substrate 101 may be equally as wide as the maximum size D2 of an opening between the first mask patterns 110a or similar thereto. According to exemplary embodiments, the width of D3 of the thin film layer 130 may be smaller than the maximum size D2 of the opening, and the thin film layer 130 may be positioned in a location offset from the opening by a predetermined distance.

The thin film layer 130 may be formed by using, for example, a Physical Vapor Deposition (PVD) method. However the present inventive concept is not limited thereto. The thin film layer 130 may be formed of, for example, metal, however, the present inventive concept is not limited thereto, and diverse types of material may be used according to respective roles thereof inside a semiconductor device. The thickness T3 of the thin film layer 130 may be less than that of the mask pattern layer 110a. In addition, the thin film layer 130 may be formed on an upper surface of the substrate 101 to be spaced apart from the first mask pattern layer 110a due to the negative slope of side surfaces of the first mask pattern layer 110a.

According to an exemplary embodiment, because the thin film layer 130 can be formed from a front surface of the substrate 130, the thin film layer 130 may also be deposited on the second mask pattern layer 120a. Accordingly, in a case in which the thin film layer 130 is formed of, for example, a metallic material having a relatively large amount of stress applied thereto, an effect of the stress on the thin film layer 130 may be transferred to the lower second mask pattern layer 120a and the lower first mask pattern layer 110a. However, according to a present exemplary embodiment, because the first mask pattern layer 110a having relatively high degree of hardness can be formed below the second mask pattern layer 120a, defects caused by the deformation of the mask pattern layers 110a, 120a due to the stress applied to the thin film layer 130 may be prevented.

In addition, in a case in which the thin film layer 130 is deposited on side surfaces of the first mask pattern layer 110a, due to the first mask pattern layer 110a having a negative slope, the thin film layer 130 on the side surface of the first pattern layer 110a can be prevented from being connected to the thin film layer 130 on the substrate 101 and remained without being removed.

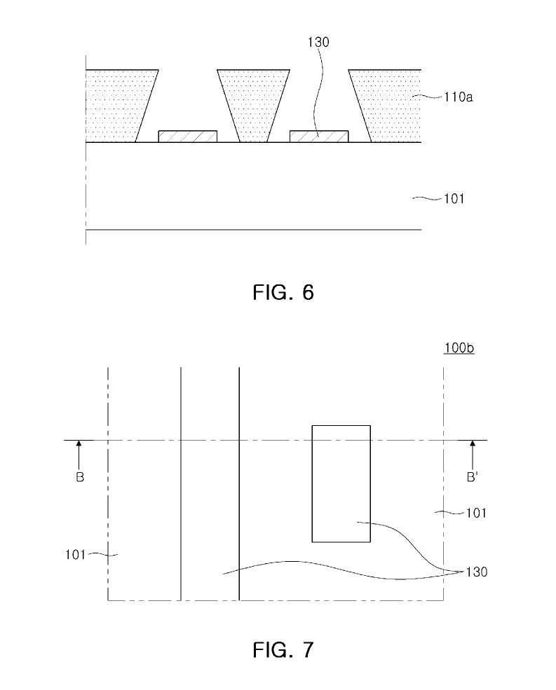

With reference to FIG. 6, the second mask pattern layer 120a can be removed. As the second mask pattern layer 120a is removed, a lift off process in which the thin film layer 130 on the second mask pattern layer 120a can be removed simultaneously therewith may be performed.

Thereby, the thin film layer 130 and the first pattern layer 110a remain on the substrate 101. The thin film layer 130 and the first pattern layer 110a may be components of semiconductor devices. According to a present exemplary embodiment, the thin film layer 130 may be patterned and formed simultaneously by being deposited on the substrate 101 without a separate patterning process by adopting a lift off process. Therefore, the process may be simplified.

FIG. 7 is a schematic plan view illustrating an exemplary semiconductor device pattern implemented by applying the method of forming patterns for a semiconductor device according to an exemplary embodiment of the present disclosure.

With reference to FIG. 7, the semiconductor device 100b may include a thin film layer 130 having a linear form and a rectangular form extended in a single direction

The thin film layer 130 may be a layer having tensile stress or compressive stress applied thereto, and may be formed of, for example, a metallic or dielectric material. According to a present exemplary embodiment, the shape of the thin film layer 130 is exemplary, and the thin film layer 130 may be manufactured in diverse manners to have different shapes.

The substrate 101 may be an ordinary semiconductor substrate such as a silicon (Si) substrate. Moreover, the substrate 101 may include the semiconductor substrate and a portion of semiconductor devices formed on the semiconductor substrate.

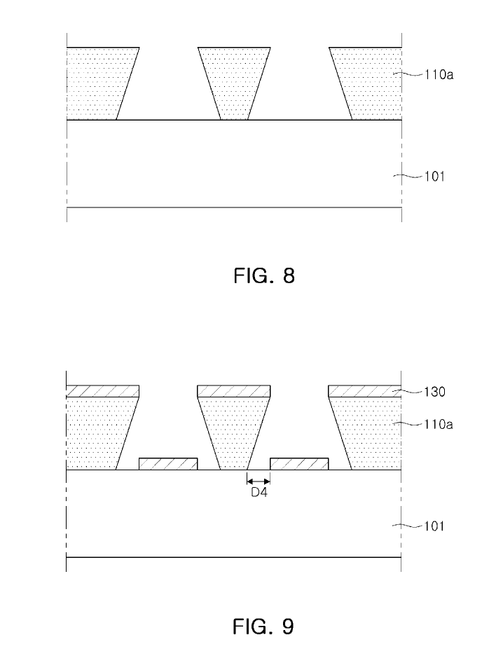

FIGS. 8 through 10 are schematic cross-sectional views illustrating, in sequence, the method of forming patterns for a semiconductor device according to an exemplary embodiment of the present disclosure. FIGS. 8 through 10 depict cross-sectional views taken along line B-B′ of FIG. 7.

In the following description provided with reference to FIGS. 8 through 10, descriptions overlapped with those in reference to FIGS. 2 through 7 are omitted. With reference to FIG. 8, the first mask pattern layer 110a may be formed on the substrate 101. As described in detail with reference to FIGS. 2 through to 4, the first mask pattern layer 110a may be formed byway of sequentially forming the first mask layer 110 and the second mask layer 120, and forming the second mask pattern layer 120a by patterning the second mask layer 120 thereafter, and etching the first mask layer 110 through the use thereof. A negative slope may be formed on side surfaces of the first mask pattern layer 110a.

According to the present exemplary embodiment, after the first mask pattern layer 110a is formed, removing the second mask pattern layer 120a may be further performed. Accordingly, only the first mask pattern layer 110a may remain on the substrate 101.

With reference to FIG. 9, the thin film layer 130 may be formed on the substrate 101 on which the first mask pattern layer 110a is formed.

By the negative slope in side surfaces of the first mask pattern layer 110a, the thin film layer 130 may be formed to be spaced apart from the first mask pattern layer 110a on an upper surface of the substrate 101 at a predetermined distance D4.

According to the exemplary embodiment, the thin film layer 130 may be formed at a relatively high temperature. As the second mask pattern layer 120a can be removed in advance, it is possible to form the thin film layer 130 at a temperature higher than that of a softening point of the second mask pattern layer 120a. The thin film layer 130 may be formed at a temperature higher than, for example, 150° C. In this case, as the first mask pattern layer 110a can be formed of a material having a high temperature stability which is higher than that of the second mask pattern layer 120a, it may not be affected.

In a case in which the thin film layer 130 is formed of a metallic material having a relatively large amount of stress applied thereto, the effect of stress applied to the thin film layer 130 on the first mask pattern layer 110a may be transferred to the first mask pattern layer 110a therebelow. However, according to the exemplary embodiment, as the hardness of the first mask pattern layer 110a can be relatively great, the first mask pattern layer 110a can be prevented from being deformed due to the stress applied to the thin film layer 130. In addition, in a case in which the thin film layer 130 is formed at a high temperature, as the second mask pattern layer 120a is removed, an evaporation chamber or the like can be prevented from being polluted by the second mask pattern layer 120a. For example, in a case in which the thin film layer 130 includes copper (Cu), it is possible to form the thin film layer 130 at a high temperature without defects, as well as to easily perform patterning without performing a separate etching process.

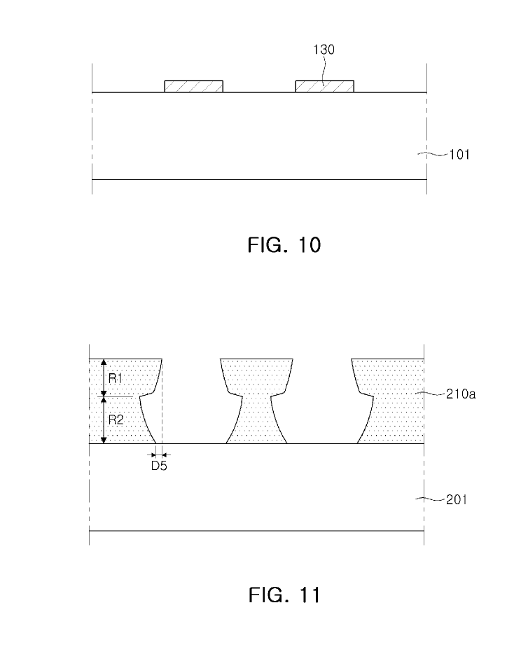

With reference to FIG. 10, the second mask pattern layer 110a can be removed. That is, in this step, a lift off process of the first mask pattern layer 110a is performed, whereby the thin film layer 130 on the first mask pattern layer 110a may also be removed simultaneously. The first mask pattern layer 110a may be removed by using a Buffered Oxide Etchant solution of hydrogen fluoride (HF) mixed with ammonium fluoride (NH₄F).

After removing the first mask pattern layer 110a, a patterned thin film layer 130 remains on the substrate 101. According to the exemplary embodiment, the thin film layer 130 may be simultaneously formed and patterned, by being deposited on the substrate 101 without a separate patterning process, therefore the process may be simplified

According to the exemplary embodiment, as described in detail referring to FIG. 8, after the forming of the first mask pattern layer 110a, a process of removing the second mask pattern layer 120a can be performed. However, according to exemplary embodiments, it is possible to remove the upper second mask pattern layer 120a simultaneously with removing the first mask pattern layer 110a at this stage.

FIG. 11 is a schematic cross-sectional view illustrating a process of the method of forming patterns for a semiconductor device according to an exemplary embodiment of the present disclosure.

With reference to FIG. 11, a first mask pattern layer 210a can be formed. The first mask pattern layer 210a may correspond to the first mask pattern layer 110a described with reference to FIGS. 4 and 8. Meanwhile, the first mask pattern layer 210a of the exemplary embodiment may include a first region R1 having a negative slope and a second region R2 having a positive slope, different to the first mask pattern layer 110a of FIGS. 4 and 8. Accordingly, byway of including the negative slope region in at least a portion of the first mask pattern layer 210a, the first mask pattern layer 210a may have a lower surface having a width less than that of an upper surface and have a lower edge portion offset from upper edge portions in a center direction by a predetermined distance D5.

The first mask pattern layer 210a may be manufactured, for example, by firstly forming the first region R1 by dry etching, then forming the second region R2 by wet etching on a first mask layer having homogenous film properties. However, the present inventive concept is not limited thereto, according to the exemplary embodiment, by forming the first mask pattern layer 210a to include layers having varied etching characteristics, a side surface having a shape as illustrated in FIG. 11 may be formed.

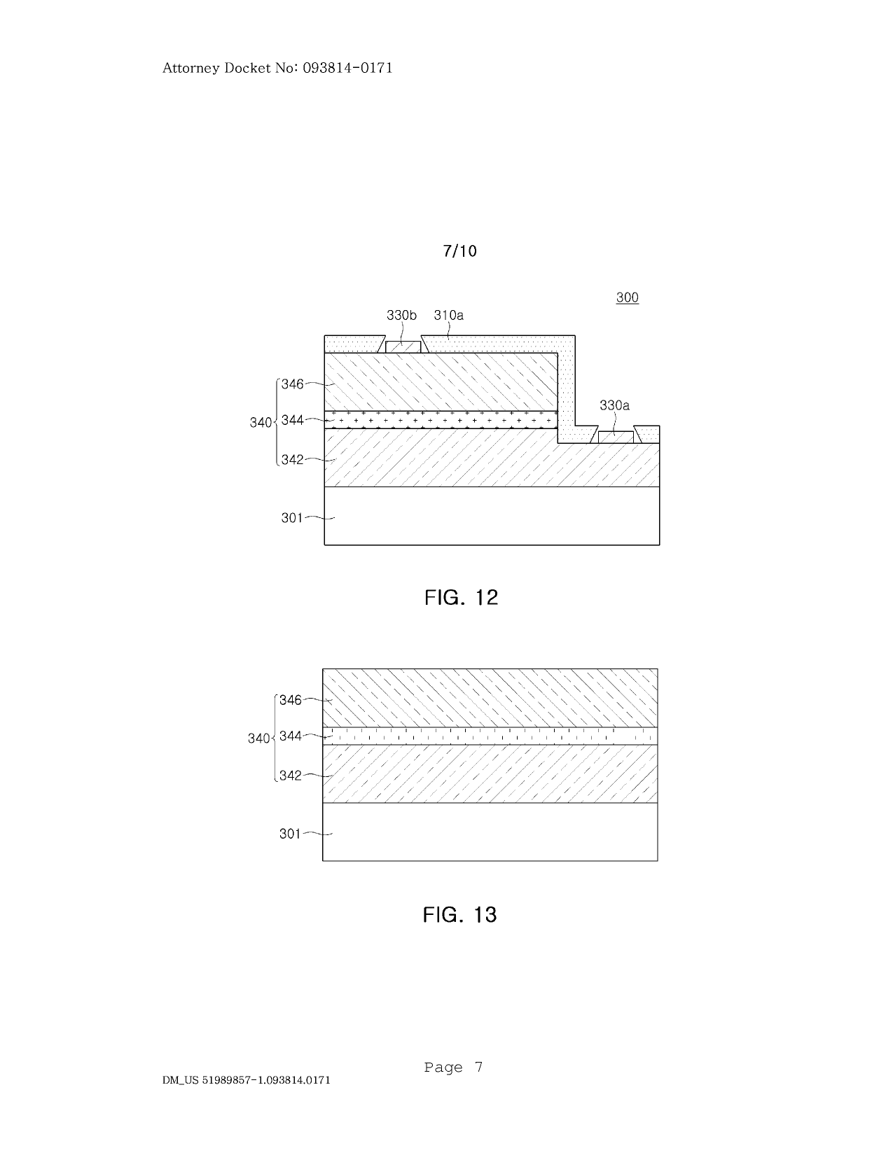

FIG. 12 is a schematic cross-sectional view illustrating a semiconductor device according to an exemplary embodiment of the present disclosure.

With reference to FIG. 12, a semiconductor device 300 according to the exemplary embodiment may include a substrate 301, a light emitting structure 340 mounted on the substrate 301, a first electrode 330a, a second electrode 330b, and a passivation layer 310a. The light emitting structure 340 may include a first conductivity type semiconductor layer 342, an active layer 344 and a second conductivity type semiconductor layer 346 sequentially stacked. According to the exemplary embodiment, a Light Emitting Diode (LED), as an exemplary semiconductor device manufactured by applying the method of forming patterns for a semiconductor device, will be exemplified for ease of explanation.

The substrate 301 may be provide as a substrate for semiconductor growth, the substrate 301 may be made of a semiconducting, insulating or conducting material such as sapphire, SiC, MgAl₂O₄, MgO, LiAlO₂, LiGaO₂, GaN or the like. A sapphire substrate widely used as a semiconductor growth substrate can be formed of a crystal having Hexa-Rhombo R3c symmetry, and having a lattice constant of 13.001 Å (angstrom) on a C-axis and a lattice constant of 4.758 Å on an A-axis. Orientation planes of the sapphire substrate include a C (0001) plane, an A (1120) plane, an R (1-102) plane, and the like. In particular, the C plane can be mainly used as a substrate for nitride growth as it facilitates the growth of a nitride film and can be stable at high temperatures. Meanwhile, although not depicted in the drawings, a set of concavo-convex patterns may be formed in an upper surface of the substrate 301, such that on a growth surface of semiconductor layers, crystalline properties and light emitting efficiency of semiconductor layers may be improved, due to the concavo-convex structure.

Although not depicted at drawings, a buffer layer provided to improve crystallite formation by alleviating stress applied to the first conductivity type semiconductor layer 342 may be further disposed on the substrate 301.

The first conductivity type semiconductor layer 342, and the second conductivity type semiconductor layer 346 may be formed of semiconductors doped with n-type and p-type impurities, but are not limited thereto, and may be formed of p-type and n-type semiconductor materials. The first and the second conductivity type semiconductor layers 342 and 346 may be formed of a nitride semiconductor materials, for example, a material having a composition of AlₓIn_{y}Ga_{1-x-y}N, where 0≦x≦1, 0≦y≦1, and 0≦x+y≦1, each of which may be formed as a single layer or as a set of layers having different characteristics in terms of doping concentration, composition and the like. However, the first and second conductivity-type semiconductor layers 342 and 346 may also be formed of an AlInGaP or AlInGaAs semiconductor, besides the nitride semiconductor

The active layer 344, disposed between the first and second conductivity-type semiconductor layers 342 and 346, may emit light having a predetermined level of energy according to the recombination of electrons and holes and may have a multi-quantum well (MQW) structure in which quantum well layers and quantum barrier layers are alternately laminated. For example, in the case of the nitride semiconductor, a GaN/InGaN structure may be used. Alternatively, a single quantum well (SQW) structure may also be used.

The first and second electrodes 330a and 330b may be electrically connected to the first and second conductivity-type semiconductor layers 342 and 346, respectively. The first and second electrodes 330a and 330b may be disposed in an area spaced apart from an edge portion of a passivation layer 310a on the first and second conductivity-type semiconductor layers 342 and 346, respectively. The thicknesses of the first and second electrodes 330a and 330b may be less than that of the passivation layer 310a, but are not limited to the exemplary thicknesses as illustrated in the figures.

For example, the first and second electrodes 330a and 330b may be formed of one or more of silver (Ag), aluminum (Al), nickel (Ni), chromium (Cr), and the like. According to exemplary embodiments, the first and second electrodes 330a and 330b may be transparent electrodes, and, for example, may be formed of ITO (Indium tin Oxide), AZO (Aluminum Zinc Oxide), IZO (Indium Zinc Oxide), ZnO, GZO(ZnO:Ga), In₂O₃, SnO₂, CdO, CdSnO₄, or Ga₂O₃. Although not illustrated in the drawings, an ohmic electrode layer may be further disposed on the second conductivity-type semiconductor layer 346. For example, the ohmic electrode layer may include p-GaN including high concentration p-type impurities. Alternatively, the ohmic electrode layer may be formed of a metal or a transparent conductive oxide.

The passivation layer 310a may be formed of a dielectric or an insulating material, and, for example, may be PEOX. A density of the passivation layer 310a may be changed in a direction perpendicular to the substrate 301, and lower portion thereof may have relatively lower density than upper portion. A porosity of the passivation layer 310a may be changed in a direction perpendicular to the substrate 301, and a lower portion thereof may have relatively greater density than an upper portion.

FIGS. 13 through 15 are schematic cross-sectional views illustrating the method of manufacturing a semiconductor device according to an exemplary embodiment of the present disclosure. FIGS. 13 through 15 depict a method of manufacturing the semiconductor device 300 of FIG. 12.

With reference to FIG. 13, the light emitting structure 340 may be sequentially stacked on the substrate 301. The light emitting structure 340 can be formed by sequentially growing a first conductivity type semiconductor layer 342, an active layer 344 and a second conductivity type semiconductor layer 346 by metal organic chemical vapor deposition (MOCVD), hydride vapor phase epitaxy (HVPE), molecular beam epitaxy (MBE), or the like.

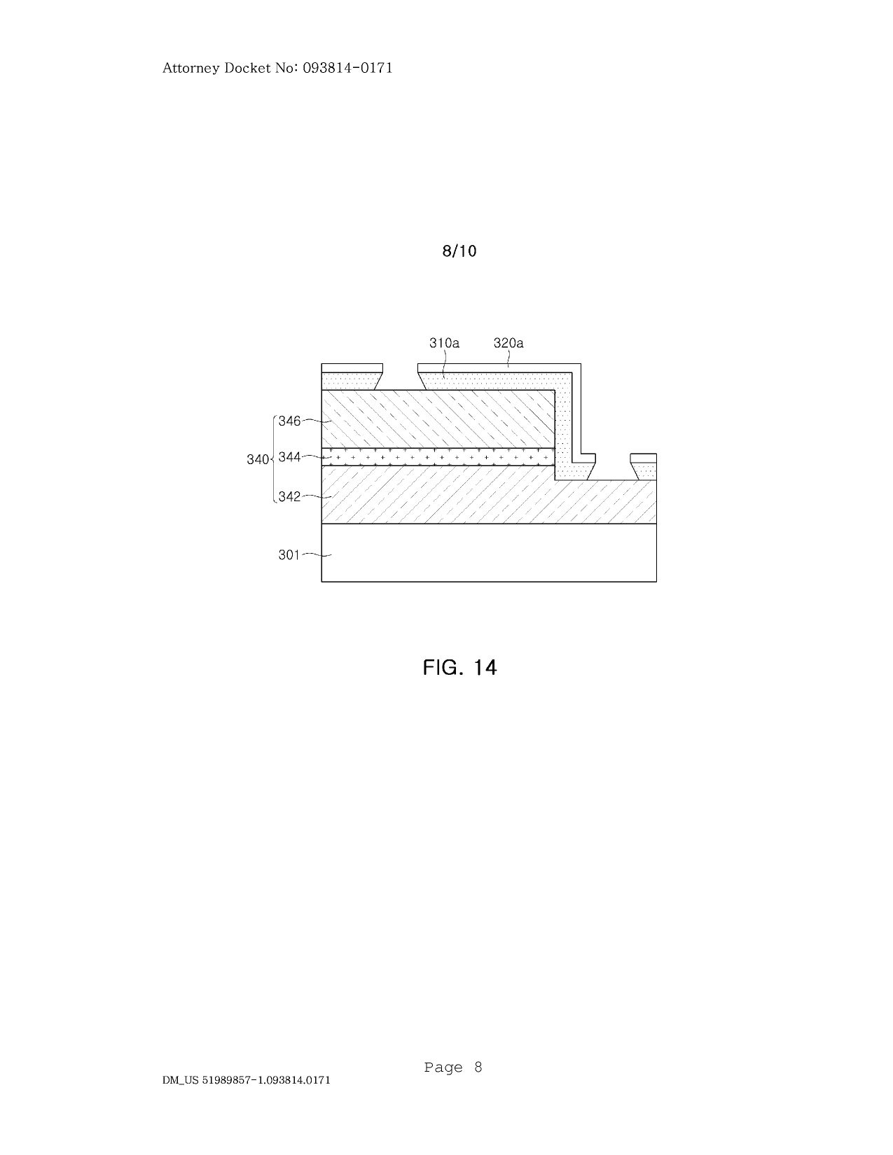

With reference to FIG. 14, firstly, by removing a portion of the light emitting structure 340, a portion of the first conductivity type semiconductor layer 342 may be exposed.

Then, a passivation layer 310a and a photo-resist layer 320a may be formed on an upper surface of the light emitting structure 340. The formation of the passivation layer 310a and the photo-resist layer 320a may be performed by the process of forming the first mask pattern layer 110a and the second mask pattern layer 120a as described in detail with reference to FIGS. 2 through 4. That is, after materials forming the passivation layer 310a and the photo-resist layer 320a are laminated, the photo-resist layer 320a can be patterned, and the passivation material 310a can be patterned by using the patterned photo-resist layer 320a. As a result, the side surface of the passivation layer 310a can have a negative slope.

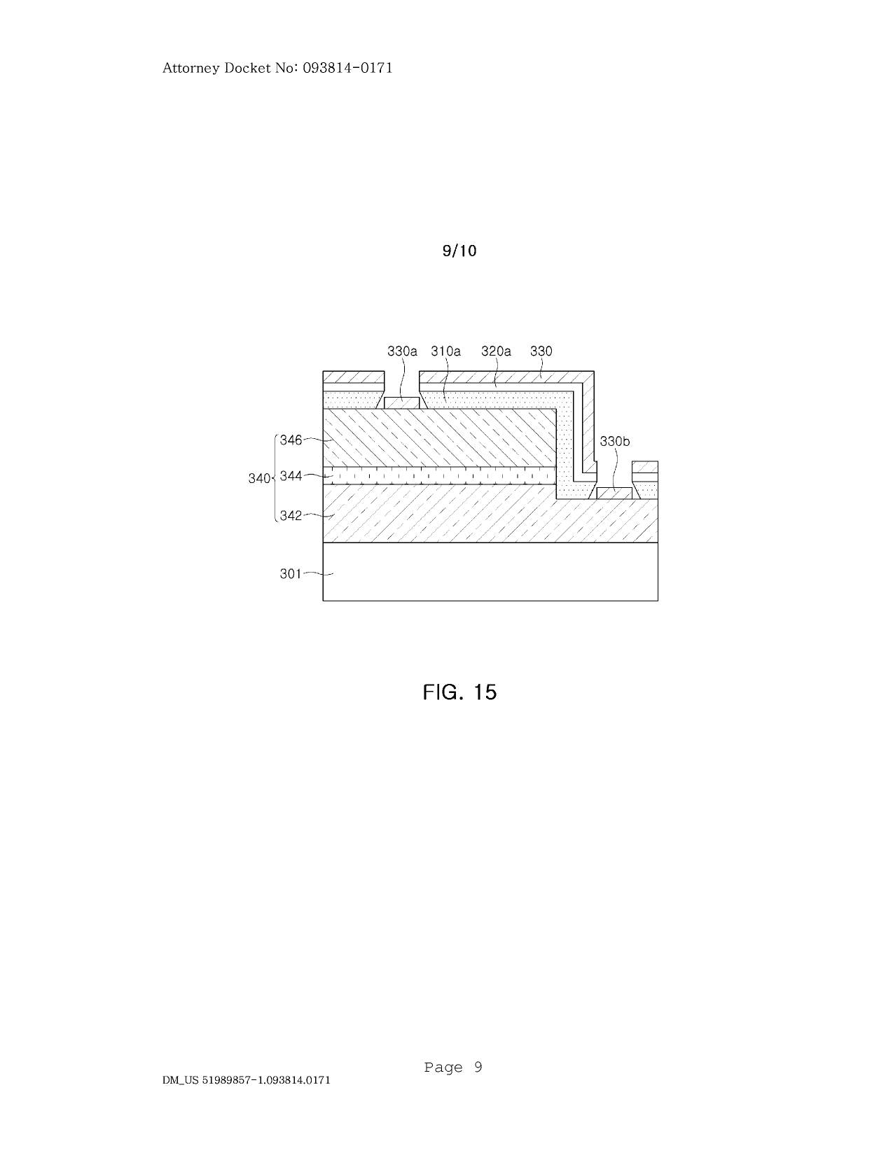

With reference to FIG. 15, the first electrode 330a and the second electrode 330b are disposed on the light emitting structure 340.

The formation of the first electrode 330a and the second electrode 330b may be performed by the process of forming the thin film layer 130 as described in detail with reference to FIGS. 5 and 6. The first and second electrodes 330a and 330b may be formed on the surfaces of the light emitting structure 340 exposed through the passivation layer 310a by depositing the metallic layer 330 by using the passivation layer 310a as a mask layer. The metallic layer 330 may be deposited by, for example, a physical vapor deposition (PVD) process such as sputtering, electron beam evaporation, or the like.

Then, by removing the photo-resist layer 320a and the metallic layer 330 on the upper surface of the photo-resist layer 320a, the semiconductor device 300 of FIG. 12 may be manufactured.

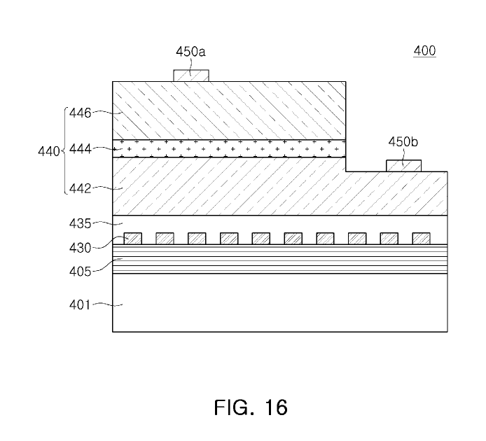

FIG. 16 is a schematic cross-sectional view illustrating a semiconductor device according to an exemplary embodiment of the present disclosure.

With reference to FIG. 16, a semiconductor device 400 according to the present embodiment may include a substrate 401, a reflective layer 405 disposed on the substrate 401, a buffer layer 435 and a light emitting structure 440, and may further include a first electrode 450a and a second electrode 450b disposed on the light emitting structure 440. The light emitting structure 440 may include a first conductivity type semiconductor layer 442, an active layer 444 and a second conductivity type semiconductor layer 446, sequentially stacked. According to the exemplary embodiment, a Light Emitting diode, as an exemplary semiconductor device manufactured by applying the method of forming patterns for a semiconductor device described with reference to FIGS. 7 through 10 will be exemplified for explanation.

The semiconductor device 400 according to an exemplary embodiment further includes the reflective layer 405 and a protrusions 430 disposed on the reflective layer 405, unlike the semiconductor device 300 of FIG. 12. The reflective layer 405 can be a reflective structure for redirecting light generated in the active layer 444 and travelling from the substrate 401 toward the top of the light emitting structure 440. The reflective layer 405 may be a Distributed Bragg Reflector (DBR) or an Omni-Directional Reflector (ODR) layer. The reflective layer 405 may be a structure of layers having different refractive indices alternately laminated.

The protrusions 430 may protrude from an upper surface of the reflective layer 405 at regular intervals, and may have various shapes such as a dome, a polypyramid, a cone, a polyprism, or a cylinder.

The protrusions 430 may be formed of a material having a refractive index lower than that of the reflective layer 405 and the light emitting structure 440, and may also be formed of a light transmissive material. For example, the protrusions 430 may be formed of a light transmissive material selected from the group consisting of SiOₓ, SiNₓ, Al₂O₃, HfO, TiO₂, ZrO, ZnO and combinations thereof. In the case in which the protrusions 430 are formed of a light transmissive material, the protrusions 430 may correct a path of light without a loss of incident light. The protrusions 430 may correct the path of incident light in a direction close to that of a normal path due to low refractive indices thereof, and may increase an amount of light reflected by the reflective layer 405.

The buffer layer 435 formed on the protrusions 430 may alleviate stress exerted on the first conductivity-type semiconductor layer 442 to improve crystalline properties, and may be formed of AlN, GaN or AlGaN.

In particular, the protrusions 430 of the present embodiment may be formed by using the method of forming patterns for a semiconductor device as described with reference to FIGS. 7 through 10. For example, in the case in which the protrusions 430 are formed of materials such as TiO₂ or TaO, both dry and wet etchings thereof may be difficult to perform and may be deposited at a temperature higher than about 200° C., the method of forming patterns for a semiconductor device according to present embodiment may be used. In this case, a material for forming the protrusions 430 may be deposited in a state in which a mask layer having a relatively low degree of high-temperature stability, such as a photoresist layer, may not be present, whereby defects in the semiconductor device and pollution of the deposition chamber may be prevented. In addition, the protrusions 430 may be patterned with the shape of the protrusions 430, simultaneously with the deposition of the material, accordingly, the present exemplary embodiment provides an advantage in that the etching process may be omitted. According to the exemplary embodiment, the reflective layer 405 may also include patterned layers formed by a method of forming patterns for a semiconductor device.

While exemplary embodiments have been shown and described above, it will be apparent to those skilled in the art that modifications and variations could be made without departing from the spirit and scope of the present disclosure as defined by the appended claims.

What is claimed is:

1. A method of forming patterns for a semiconductor device, comprising:
sequentially forming a first mask layer and a second mask layer on a substrate;
forming a second mask pattern layer by patterning the second mask layer;
forming a first mask pattern layer having a negative slope portion, the width of which decreases from an area adjacent to the second mask pattern layer to the substrate, by etching the first mask layer exposed through the second mask pattern layer; and
forming a thin film layer on the substrate exposed through the first mask pattern layer.

2. The method of forming patterns for a semiconductor device of claim 1, wherein the thin film layer is formed on an upper surface of the substrate to be spaced apart from the first mask pattern layer.

3. The method of forming patterns for a semiconductor device of claim 1, wherein the step of forming the thin film layer includes,
depositing a material for forming the thin film layer on the substrate on which the first mask pattern layer and the second mask pattern layer are sequentially formed; and
removing the second mask pattern layer.

4. The method of forming patterns for a semiconductor device of claim 1, further comprising:
removing the second mask pattern layer before the forming the thin film layer.

5. The method of forming patterns for a semiconductor device of claim 1, further comprising:
removing the first mask pattern layer after the forming of the thin film layer.

6. The method of forming patterns for a semiconductor device of claim 1, wherein the step of forming the thin film layer is performed at a temperature higher than a temperature of a softening point of the second mask pattern layer.

7. The method of forming patterns for a semiconductor device of claim 1, wherein the step of forming the first mask pattern layer includes wet etching at least a portion of the first mask layer.

8. The method of forming patterns for a semiconductor device of claim 1, wherein the first mask layer includes a material, a hardness of which is higher than a hardness of the second mask layer.

9. The method of forming patterns for a semiconductor device of claim 1, wherein a density of the first mask layer changes in a vertical direction to the upper surface of the substrate.

10. The method of forming patterns for a semiconductor device of claim 1, wherein a porosity of the first mask layer changes in a vertical direction to the upper surface of the substrate.

11. The method of forming patterns for a semiconductor device of claim 10, wherein the porosity of the first mask layer is greater in the vicinity of the substrate than that in the vicinity of the second mask layer.

12. The method of forming patterns for a semiconductor device of claim 11, wherein the porosity of the first mask layer gradually increases in an area facing the substrate from an area facing the second mask layer.

13. The method of forming patterns for a semiconductor device of claim 1, wherein the thin film layer has tensile stress or compressive stress applied thereto.

14. The method of forming patterns for a semiconductor device of claim 1, wherein the first mask layer includes a dielectric material or an insulating material.

15. A method of forming patterns for a semiconductor device, comprising:
forming a mask pattern layer having a negative slope area on a substrate, wherein the mask pattern layer includes non-photosensitive material; and
forming a thin film layer on a substrate exposed through the mask pattern layer.

16. A method of forming patterns for a semiconductor device, comprising:
sequentially forming a first mask layer and a second mask layer on a substrate;
forming a second mask pattern layer by patterning the second mask layer;
forming a first mask pattern layer having a first region with a negative slope and a second region with a positive slope,
wherein a width of the first mask pattern layer on a lower surface is less than the width of the first mask pattern layer on an upper surface, and
wherein a lower edge portion of the first mask pattern layer offsets from an upper edge portions of the first mask pattern layer in a center direction by a predetermined distance; and
forming a thin film layer on the substrate exposed through the first mask pattern layer.

17. The method of forming patterns for a semiconductor device of claim 16, wherein the step of forming the thin film layer includes,
depositing a material for forming the thin film layer on the substrate on which the first mask pattern layer and the second mask pattern layer are sequentially formed; and
removing the second mask pattern layer.

18. The method of forming patterns for a semiconductor device of claim 16, further comprising:
removing the second mask pattern layer before the forming the thin film layer.

19. The method of forming patterns for a semiconductor device of claim 16, wherein the step of forming the thin film layer is performed at a temperature higher than a temperature of a softening point of the second mask pattern layer.

20. The method of forming patterns for a semiconductor device of claim 16, wherein the step of forming the first mask pattern layer includes wet etching at least a portion of the first mask layer.
